(19) United States
(12) Patent Application Publication
(10) Pub. No.: US 2012/0104917 A1
(43) Pub. Date: May 3, 2012

(54) SERVER RACK

(75) Inventor: CHEN-LU FAN, Tu-Cheng (TW)

(73) Assignee: HON HAI PRECISION INDUSTRY CO., LTD., Tu-Cheng (TW)

(21) Appl. No.: 13/172,286

(22) Filed: Jun. 29, 2011

(30) Foreign Application Priority Data
Nov. 2, 2010 (CN) 201010528451.4

(51) Int. Cl. H05K 5/02

(52) U.S. Cl. 312/326

(57) ABSTRACT

A server rack includes a case, a rear door panel and a latching device. The case defines an opening; the rear door panel is rotatably secured to the case; the latching device includes a controlling member secured to the positioning member and a positioning member secured to the controlling member; the positioning member is slidable relative to the rear door panel, to be engaged in the opening or disengaged from the opening; the controlling member is adapted to slide and lock the positioning member.

### BACKGROUND

1. Technical Field

The present disclosure relates to a server rack, and particularly to a server rack with a rear door panel that can be conveniently opened and closed.

2. Description of Related Art

A server rack houses electronic equipment, such as data storage devices and power supplies. The server rack usually includes two rectangular frames, a plurality of supports connected to the two rectangular frames, and a rear door panel secured to the two rectangular frames and the supports. The rear door panel can be opened when a server is needed to be added in or removed from the sever rack.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a server rack in accordance with an embodiment.

FIG. 2 is an enlarged view of an encircled portion II of FIG. 1.

FIG. 3 is an isometric view of a linking beam and a positioning body of FIG. 1.

FIG. 4 is assembled, isometric view of FIG. 1, and a rear door panel is in place and closed.

FIG. 5 is similar to FIG. 4, but the rear door panel is in place and open.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

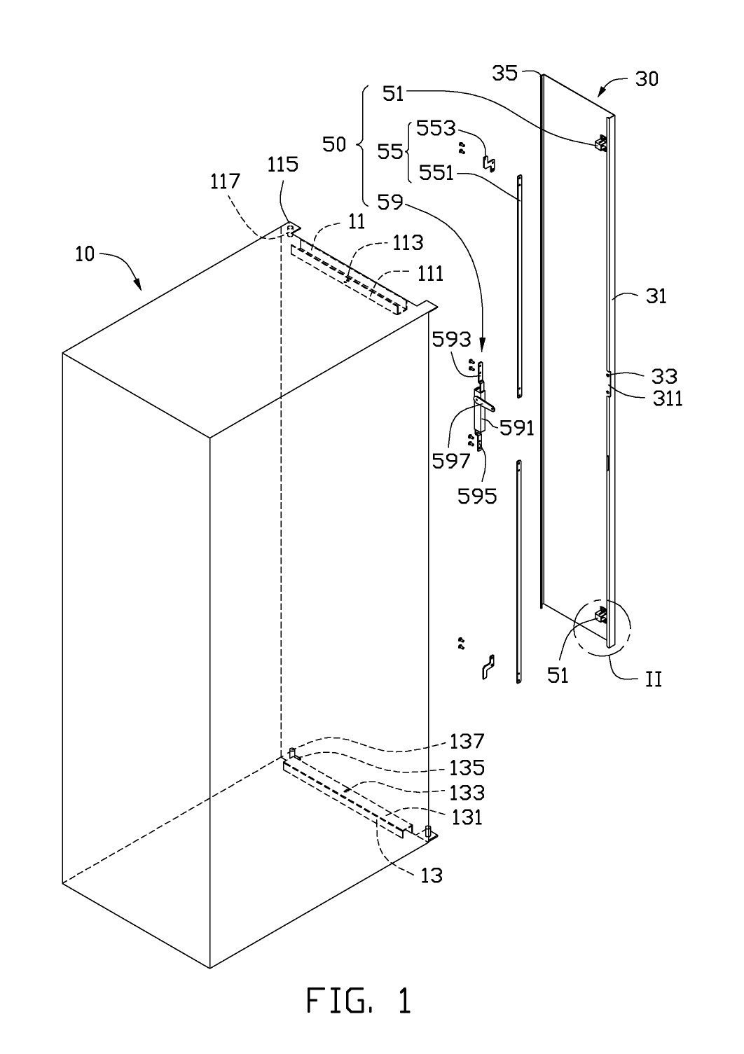

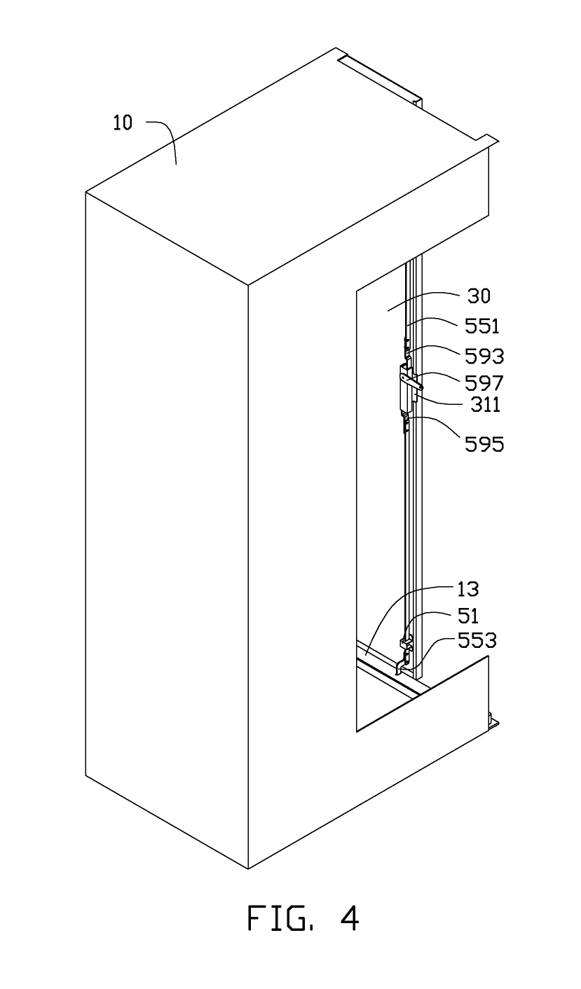

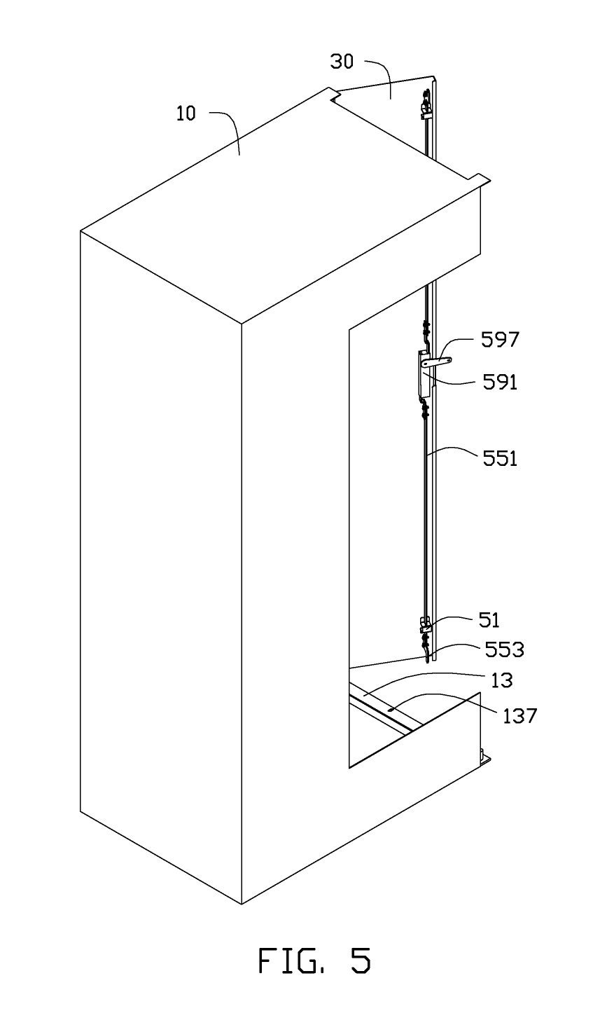

Referring to FIG. 1, a server rack in accordance with an embodiment includes a case 10 and two rear door panels 30 (just one rear door panel with a latching device 50 is shown in FIG. 1, FIG. 4 and FIG. 5).

The case 10 includes a first beam 11 and a second beam 13. Two first mounting extensions 115 extend from the case 10 and located on two opposite ends of the first beam 11. Two second mounting extensions 135 extend from two opposite ends of the second beam 13. The two first mounting extensions 115 are substantially parallel and coaxial to the two second mounting extensions 135. A first mounting post 117 extends down from each first mounting piece 115 towards the second mounting piece 135. A second mounting post 137 extends up from each second mounting piece 135 towards the first mounting piece 115. The first beam 11 includes a bottom wall 111. The bottom wall 111 is substantially perpendicular to the second mounting post 137, and defines a first opening 113. The second beam 13 includes a top wall 131. The top wall 131 is substantially perpendicular to the second mounting post 137, and defines a second opening 133.

A first side edge of the rear door panel 30 defines a receiving slot 35. One of the first mounting post 117 and one of the second mounting post 137 are engaged in opposite ends of the receiving slot 35, to rotatably locate the rear door panel 30 against the case 10. A flange 31 extends from a second side edge of the rear door panel 30. The flange 31 defines a notch 311. The rear door panel 30 defines two positioning holes 33, and the latching device 50 is installed in the rear door panel 30.

The latching device 50 includes two limiting members 51, two positioning members 55 and a controlling member 59.

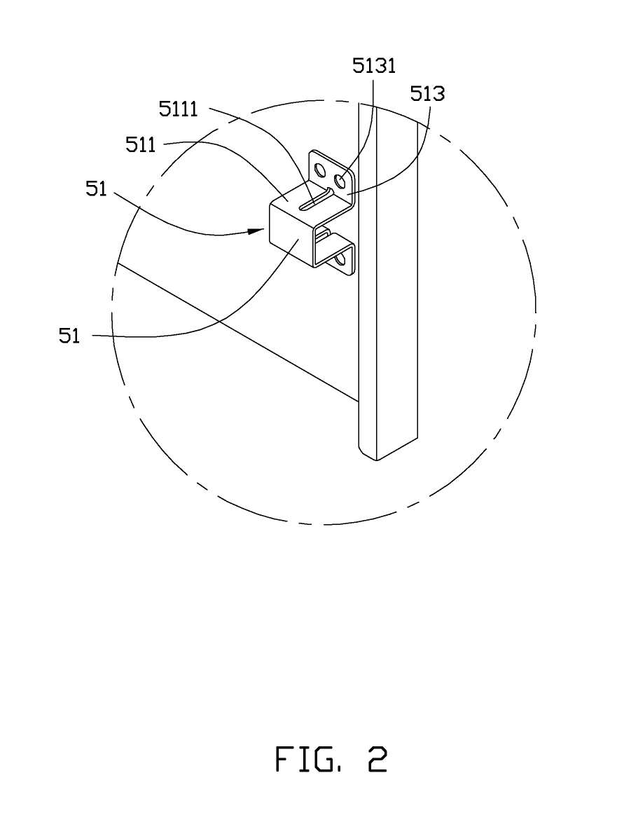

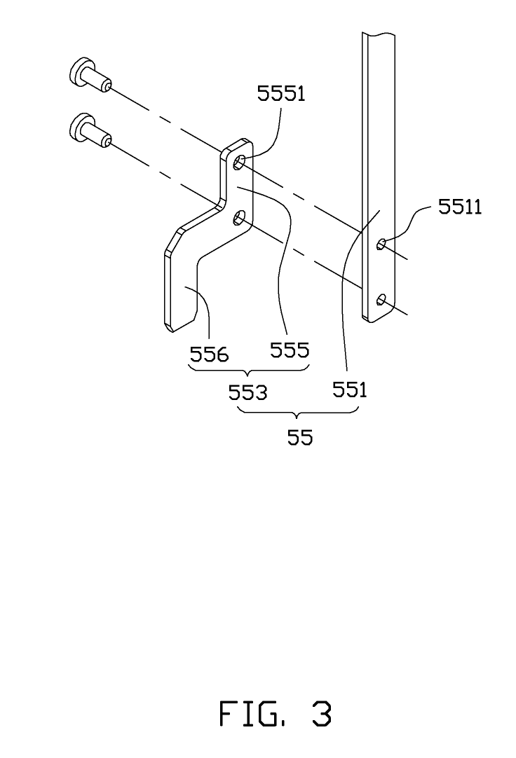

Referring to FIG. 2 and FIG. 3, each limiting member 51 includes a body 511 and two positioning extensions 513 extending from two opposite side edges of the body 511. The two positioning extensions 513 are substantially coplanar. The body 511 defines a through hole 5111. In one embodiment, the through hole 5111 is substantially rectangular. Each positioning piece 513 defines two positioning holes 5131. Each positioning member 55 includes a linking beam 551 and a positioning body 553. The linking beam 551 defines two first mounting holes 5511. The positioning body 553 includes a first body 555 and a second body 556. The first body 555 defines a second mounting hole 5551. In one embodiment, the positioning body 553 is substantially “Z” shaped, the cross-section of the positioning body 553 and of the linking beam 551 are rectangular.

The controlling member 59 includes a controlling portion 591, a first sliding piece 593 and a second sliding piece 595. The controlling portion 591 defines two through holes (not shown), and a rotating piece 597 located on the controlling portion 591. The first sliding piece 593 and the second sliding piece 595 are secured to two opposite ends of the controlling portion 591 and can, in concert, extend from or retract into the controlling portion 591. The rotating piece 597 is rotatably attached to the controlling portion 591, to move the first sliding piece 593 and the second sliding piece 595 by means of a duplex rack and pinion arrangement. In one embodiment, the cross-sections of the first sliding piece 593 and the second sliding piece 595 are rectangular.

Referring to FIG. 4 and FIG. 5, in assembly of the latching device 50, the limiting member 51 is mounted to an inner surface of the rear door panel 30 through the positioning hole 5131. A locking member, such as a screw, is inserted into the positioning hole 33 and the through holes of the controlling member 59. The controlling member 59 is secured to the rear door panel 30 adjacent to the notch 311 of the flange 31. The rotating piece 597 extends into the notch 311. In one embodiment, the first sliding piece 593 and the second sliding piece 595 are substantially perpendicular to the rear door panel 30. A first end of the linking beam 551 is secured to the first body 555 of the positioning body 553, and a second end of the linking beam 551 is secured to the sliding piece 553 through the through hole 5111. In one embodiment, the first sliding piece 593, the second sliding piece 595 and the two linking beams 551 are substantially parallel to the two positioning bodies 553.

On case 10, the rear door panel 30 can be rotated open and rotated closed. In the closed position, the rotating piece 597 extends out of the notch 311 and is substantially perpendicular to the first sliding piece 593 and the second sliding piece 595. The second bodies 556 engage in the first opening 113 and the second opening 133. In the open position, the rotating piece 597 is manually raised or depressed in the notch 311, to a position substantially parallel to the sliding extensions 593 and 595, and the second bodies 556 are released from the first opening 113 and the second opening 133.

When the rear door panel 30 must be opened, the rotating piece 597 is manually turned through an angle of 90 degrees. The first sliding piece 593 is moved away from the first beam 11, and at the same time the second sliding piece 595 is moved away from the second beam 13. The two positioning bodies 553 are disengaged from the first opening 113 and the second opening 133, and the rear door panel 30 may then be swung open.

When the rear door panel 30 is rotated from the open position to the closed position the rotating piece 597 may then be rotated from a position in line with the sliding extensions, to a position at right angles to them. The sliding extensions 593 and 585 re-engage respectively with the first and second beams 11 and 13. The two positioning bodies 553 are engaged in the first opening 113 and the second opening 133, and then the rear door panel 30 is once again located in the closed position.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and the arrangement of parts within the principles of the disclosure, to the full extent indicated by the broad general meaning of the terms in which the appended claims are expressed.

What is claimed is:

1. A server rack comprising:
a case defining an opening;
a rear door panel rotatably attached to the case; and
a latching device comprising a controlling member and a positioning member connected to the controlling member, the controlling member comprising a controlling portion secured to the rear door panel and a rotating piece rotatably attached to the controlling portion;
wherein the positioning member is slidable relative to the rear door panel, the rotating piece is adapted to slide the positioning member; the rotating piece is rotatable between a first position, where the rotating piece is substantially perpendicular to the sliding piece, and the positioning member is engaged in the opening, and a second position, where the rotating piece is substantially parallel to the sliding piece, and the positioning member is disengaged from the opening.

2. The server rack of claim 1, wherein a cross-section of the positioning member is rectangle.

3. The server rack of claim 1, wherein the controlling member further comprises a sliding piece, and the sliding piece is attached in the controlling portion and slidable relative to the controlling portion.

4. The server rack of claim 3, wherein a cross-section of the sliding piece is rectangle.

5. The server rack of claim 3, wherein the positioning member comprises a linking beam and a positioning body, the linking beam is secured to the sliding piece.

6. The server rack of claim 5, wherein the positioning body is secured to the linking beam and located in a first end of the linking beam, the sliding piece is located in a second end of the linking beam.

7. The server rack of claim 3, wherein the latching device further comprises a limiting member, the limiting member is secured to the rear door panel and defines a through hole, and the sliding piece is received in the through hole.

8. The server rack of claim 7, wherein the through hole is rectangle.

9. The server rack of claim 1, wherein a flange extends from a first side edge of the rear door panel and defines a notch, the rotating piece extends out of the notch when the rotating piece is in the first position.

10. The server rack of claim 1, wherein a receiving slot is defined in a second side edge of the rear door panel, a mounting post is located on the case, and the mounting post is received in the receiving slot.

11. A server rack comprising:
a case defining an opening;
a rear door panel rotatably attached to the case; and
a latching device comprising a controlling member and a positioning member connected to the controlling member, the controlling member comprising a controlling portion secured to the rear door panel and a rotating piece rotatably attached to the controlling portion; the positioning member is slidable relative to the rear door panel;
wherein the rotating piece is rotatable to slide the positioning member to engaged in the opening or disengaged from the opening; the controlling member comprising a rotating piece and a sliding piece, and the sliding piece connected to the rotating piece and secured to the positioning member; the sliding piece is slidable relative to the rear door panel, and the rotating piece is rotatable to slide the sliding piece; and a cross-section of the positioning member is rectangle.

12. The server rack of claim 11, wherein the rotating piece is rotatable between a first position, where the rotating piece is substantially perpendicular to the sliding piece, and the positioning member is engaged in the opening, and a second position, where the rotating piece is substantially parallel to the sliding piece, and the positioning member is disengaged from the opening.

13. The server rack of claim 11, wherein the controlling member further comprises a sliding piece, the sliding piece is attached in the controlling portion and rotatable relative to the controlling portion.

14. The server rack of claim 13, wherein a cross-second of the sliding piece is rectangle.

15. The server rack of claim 13, wherein the positioning member comprises a linking beam and a positioning body, the linking beam is secured to the sliding piece.

16. The server rack of claim 15, wherein the positioning body is secured to the linking beam and located in a first end of the linking beam, and the sliding piece is located in a second end of the linking beam.

17. The server rack of claim 12, wherein a flange extends from the rear door panel and defines a notch, the rotating piece extends out of the notch when the rotating piece is in the first position.

18. The server rack of claim 15, wherein the positioning body comprises a first body and a second body, the first body is secured to the sliding piece, the second body is engaged in the opening, and the positioning body is substantially “Z” shaped.

19. The server rack of claim 13, wherein the latching device further comprises a limiting member, the limiting member is secured to the rear door panel and defines a through hole, and the sliding piece is received in the through hole.

20. The server rack of claim 19, wherein the through hole is substantially rectangle shaped.
